(19) United States
(12) Patent Application Publication
(10) Pub. No.: US 2004/0232503 A1
(43) Pub. Date: Nov. 25, 2004

(54) Semiconductor device and method of producing the same

(76) Inventors: Shinya Sato, Hitachinaka (JP); Yasuo Onose, Naka (JP); Satoshi Shimada, Hitachi (JP); Atsuo Watanabe, Hitachiota (JP); Naohiro Monma, Hitachi (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/480,453

(22) PCT Filed: Jun. 12, 2001
(86) PCT No.: PCT/JP01/04949

(51) Int. Cl. H01L 29/82

(52) U.S. Cl. 257/417

(57) ABSTRACT

A semiconductor device for producing a movable section by using the sacrifice etching technique, wherein in order to prevent the sticking of the movable section during the sacrifice layer etching process, the movable section is formed with a reinforcing layer before the sacrifice layer etching process to temporarily increase the rigidity of the movable section, the reinforcing layer being removed after completion of the sacrifice layer etching process. The semiconductor device solves the problem of sticking of the movable section without increasing the rigidity of the movable section more than necessary, and is high in yield.

### BACKGROUND OF THE INVENTION

The present invention relates to the configuration of a semiconductor device, such as a capacitive type semiconductor pressure sensor or actuator, which is manufactured by using a sacrificial-layer etching method and also relates to a method of manufacturing the semiconductor devices.

As shown in FIG. 26, Japanese laid-open publication of international application No. Hei 08-501156 has disclosed an electrostatic capacitive type pressure gauge which is manufactured by using a sacrificial-layer etching method. Hereafter, its configuration and operation principle will be specifically described.

A fixed electrode 3 is formed on the surface of a silicon substrate 1 and a substrate protective film 5 is formed on top of it and then a diaphragm 7, made of polysilicon film, is formed on top of the protective film with a cavity 6 interposed. The electrically conductive diaphragm 7 and the oppositely-facing fixed electrode 3 form a capacitor. The cavity 6 extends to an exterior space via a plurality of etched channels 12 formed between the substrate protective film 5 and the diaphragm 7; however, on the outer periphery of the diaphragm 7, a sealing film 10, made of silicon oxide film, is formed so that the film covers the inlets of those etched channels 12. This configuration vacuum-seals the inside of the cavity 6 which functions as a pressure reference chamber used to detect pressure.

When external pressure changes, as FIG. 27 shows, the diaphragm 7 bends toward the substrate 1 side according to the pressure difference between the external pressure and the pressure in the reference chamber, thereby changing the gap between the diaphragm 7 and the fixed electrode 3, causing a capacitance change AC. This capacitance value is converted to a voltage value by means of a commonly-known switched capacitor circuit, and thus output voltage that depends on pressure can be obtained.

The main feature of the pressure gauge is the cavity 6, which functions as a pressure reference chamber, created using a sacrificial-layer etching method. In this method, as shown in FIG. 28, a sacrificial layer 106 is first created and then a diaphragm 7 is formed on top of it by using material different from the sacrificial layer 106. After that, only the sacrificial layer 106 is selectively etched by using an etching agent called etchant to obtain the desirable cavity shape.

According to this method, it is possible to manufacture a structural body which composes a diaphragm by using a thin film member such as polysilicon. Since the manufacturing process is in accordance with the LSI manufacturing technique, it is also possible to unite a pressure gauge and an output adjusting circuit, thereby reducing the pressure sensor cost. However, in this kind of surface processing type pressure gauge, there is a possibility that the following malfunctions may occur during the manufacturing process.

For the above-mentioned sacrificial-layer etching, liquid etchant is usually used. However, because the size of the cavity 6 is very small, only several μm, as shown in FIG. 29, when liquid etchant that remains in the cavity 6 dries out, a sticking problem tends to occur caused by the diaphragm 7 and the substrate 1 sticking together due to the surface tension of the liquid.

To avoid such a sticking problem, the following countermeasures are applicable. One is a method for removing a sacrificial layer by means of dry etching as described in Sensor and Actuators A67 (1998) 211-214. This thesis introduces technique for etching the silicon oxide film, which is a sacrificial layer, using an HF gas. However, because water drops are generated during the etching process, they must be intermittently removed.

Another method is freeze-drying. In this method, a substrate is washed with water after its sacrificial layer has been etched, and the minute remaining gap is filled with a liquid that sublimes before moisture dries out, and then freeze-dried. By doing so, the liquid used to fill in the gap directly transforms into a gas. Consequently, the sticking problem due to the surface tension can be avoided; however, the manufacturing equipment and processes are complicated and unsuitable for mass production.

Furthermore, the simplest method that can be considered for avoiding the sticking problem is to increase rigidity of the diaphragm so that it is stronger than the surface tension of the liquid. However, the amount of the diaphragm's displacement becomes small when pressure is applied, thereby reducing its sensitivity to pressure. Therefore, in the differential pressure sensor which has been disclosed in Japanese Application Patent Laid-open Publication No. Hei 07-7161, as shown in FIG. 30, a concept is described in which a post 13 is provided by using polymer 112, while a sacrificial layer is being etched, in order to vertically support the diaphragm so that rigidity of the diaphragm 7 is temporarily increased; and the post 13 is then removed to optimize the rigidity of the diaphragm 7. In this method, however, the manufacturing process is complicated because of making the post 13, and when the post is removed, a gap created after the sacrificial layer has been removed is connected to an exterior space. Therefore, to apply this method to an absolute pressure sensor, another process is necessary to seal the cavity space created after the post has been removed.

The objective of the present invention is to prevent the sticking problem from occurring at the movable portion during the etching process of the sacrificial layer without sacrificing the sensitivity of the movable portion by using a simple manufacturing method, thereby increasing yield during the manufacturing process.

### SUMMARY OF THE INVENTION

In a semiconductor device with a movable portion which is manufactured by using the sacrificial-layer etching technique, the present invention utilizes a reinforcing layer to be added to the movable portion during the sacrificial-layer etching process in order to temporarily increase rigidity of the movable portion and then removes said reinforcing layer after the sacrificial-layer etching process has been completed.

### BRIEF DESCRIPTION OF THE DRAWINGS

FIG. 1 is a plan view which shows a pressure gauge according to an embodiment of the present invention;

FIG. 2 is a cross-sectional view along the A-A′ line shown in FIG. 1;

FIGS. 3 through 14 show the manufacturing process of a pressure gauge according to an embodiment of the present invention;

FIG. 15 is a cross-sectional view of a pressure gauge according to another embodiment of the present invention;

FIG. 16 is a cross-sectional view of a pressure gauge according to another different embodiment of the present invention;

FIG. 17 is a cross-sectional view of a pressure sensor according to an embodiment of the present invention;

FIG. 18 is a plan view of a reference capacitance element;

FIG. 19 is a circuit diagram of a capacitance detecting circuit of a pressure sensor according to the present invention;

FIG. 20 is a drawing that explains operations of the capacitance detecting circuit of a pressure sensor according to the present invention;

FIG. 21 shows the mounting structure of a pressure sensor according to the present invention;

FIG. 22 shows an engine control system of an automobile which uses a semiconductor pressure sensor according to the present invention;

FIG. 23 shows a part of the manufacturing process of an acceleration sensor which is an embodiment of the present invention;

FIG. 24 shows a part of the manufacturing process of an infrared sensor which is an embodiment of the present invention;

FIG. 25 shows a part of the manufacturing process of an air-flow sensor which is an embodiment of the present invention;

FIG. 26 is a cross-sectional view of a conventional pressure gauge;

FIG. 27 shows the operation principle of a conventional pressure gauge;

FIG. 28 shows a part of the manufacturing process of a conventional pressure gauge;

FIG. 29 shows a part of the manufacturing process of a conventional pressure gauge; and

FIG. 30 shows a part of the manufacturing process of a conventional pressure gauge.

### DETAILED DESCRIPTION OF THE PREFERRED EMBODIMENTS

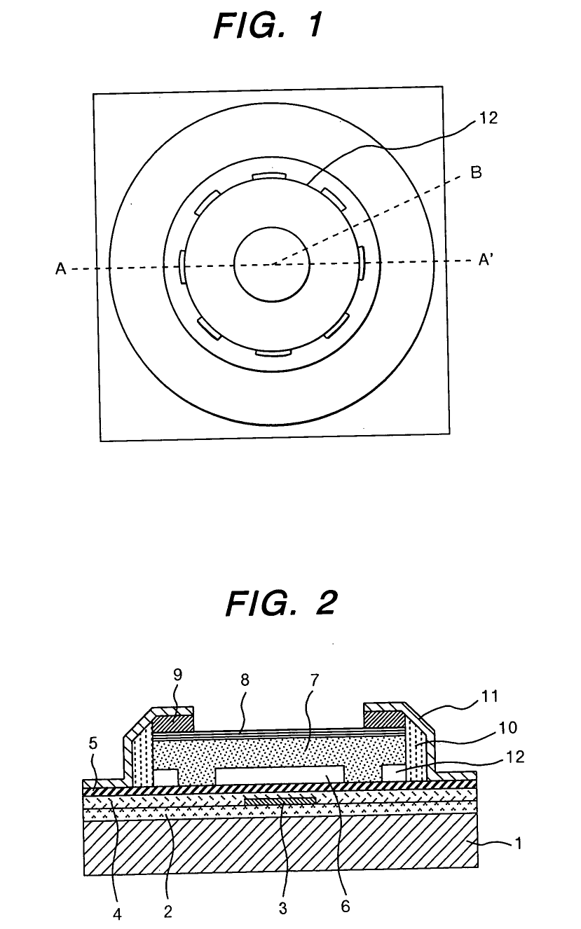

Hereafter, the present invention will be described in detail based on the embodiments shown in the drawings. FIG. 1 is a plan view which shows a semiconductor pressure sensor gauge according to an embodiment of the present invention and FIG. 2 is a cross-sectional view viewed along the A-A′ line. The configuration of the semiconductor pressure sensor gauge will be described with reference to FIGS. 1 and 2. A fixed electrode 3, made of polysilicon, is formed on top of a silicon substrate 1 with an insulating layer 2 interposed. On the fixed electrode 3, an insulating layer 4 and then a substrate protective film 5 are formed, and a diaphragm 7 which functions as a movable electrode is formed on top of the protective film with a cavity 6 interposed. On the outside of the etched channels 12 at which the cavity 6 is open to the outside, sealing material 10 is accumulated to vacuum-seal the cavity 6. In addition, an etching stopper film 8 is formed on top of the diaphragm 7, and a reinforcing layer 9 is also provided around the periphery. Furthermore, a water-proof film 11 is formed so that it covers the reinforcing layer 9 and the sealing material 10. The fixed electrode 3 and the electrically conductive diaphragm 7 form a capacitor, which detects pressure in the same manner as explained in the above-mentioned FIG. 27.

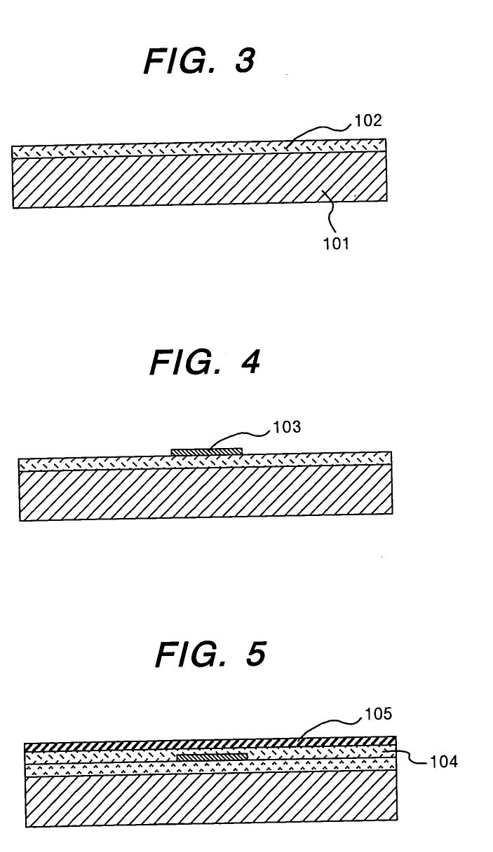

Next, the manufacturing method will be explained. The manufacturing process of this sensor is in accordance with the LSI manufacturing process. First, as shown in FIG. 3, a single-crystal silicon substrate 101 is thermally oxidized and a silicon oxide film 102, which functions as an insulating layer, is then formed on top of the substrate. Next, as shown in FIG. 4, a polysilicon film 103 is formed by means of the CVD (Chemical Vapor Deposition) on top of the silicon oxide film. Then, an impurity, such as phosphorus, is diffused to make the film conductive, and finally a fixed electrode of desired shape is obtained by using the photo-etching technique.

Next, as FIG. 5 shows, a silicon oxide film 104 and a silicon nitride film 105 are successively formed as a barrier layer on the surface of the substrate by means of the CVD. After that, as shown in FIG. 6, a sacrificial layer 106, made of phosphorus glass (PSG), is formed on top of the silicon nitride film 105 by means of the CVD. The thickness of the sacrificial layer is almost the same as the height (electrode gap) of the desired cavity which will be created later. This sacrificial layer 106 is processed by the photo-etching technique to simultaneously form the desired cavity shape, shape of the diaphragm substrate fixing portion and shape of the etched channel.

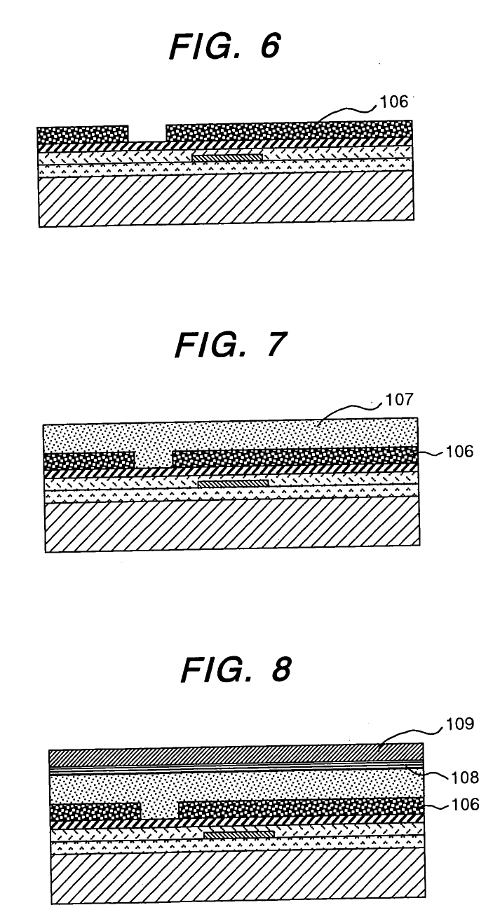

Subsequently, as FIG. 7 shows, a polysilicon film 107 which functions as a diaphragm is formed by the CVD so that it covers the sacrificial layer 106, and then an impurity, such as phosphorus, is diffused to make the film conductive. The thickness of the polysilicon film has been specified so that desired pressure sensitivity can be obtained. However, to prevent the occurrence of a sticking problem during the sacrificial-layer etching process, which will be described later in this document, as FIG. 8 shows, a silicon nitride film 108 is formed on top of the polysilicon film 107 by the CVD as an etching stopper film, and on top of it, a polysilicon film 109 is formed as a reinforcing layer 109 by the CVD. This configuration can temporarily increase rigidity of the diaphragm film.

Next, as FIG. 9 shows, a diaphragm layer, etching stopper layer and a reinforcing layer are simultaneously processed by using the photo-etching technique so that the desired diaphragm shape can be obtained. Herein, a part of the sacrificial layer 106 is exposed to the outside through the etched channel.

When this substrate is immersed in a fluoric-acid-based etchant, as FIG. 10 shows, only the sacrificial layer 106 is removed through said etched channel, and a minute cavity 6 is formed between the silicon nitride film 105 and the polysilicon film 107. The diaphragm portion to which the reinforcing layer 109 has been added has sufficient rigidity to cope with the surface tension that occurs when the etchant dries out. As a result, it is possible to prevent the occurrence of the above-mentioned sticking problem.

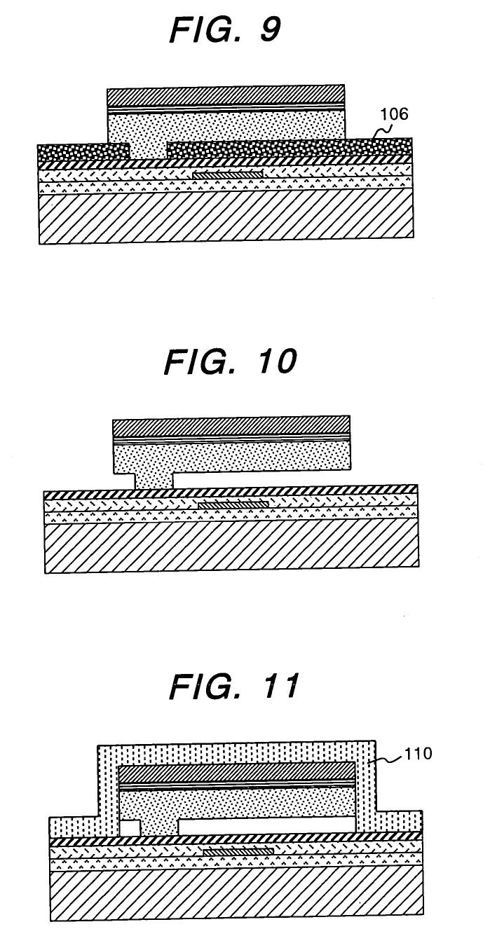

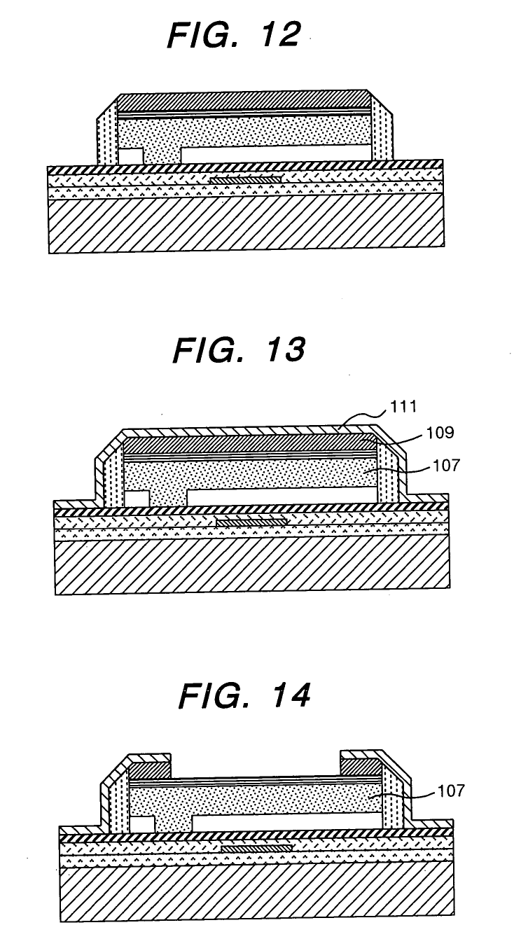

Next, as FIG. 11 shows, a silicon oxide film 110 is formed by the CVD so that it covers the substrate and the diaphragm portion. After that, as FIG. 12 shows, the film is processed into a desired shape by using the photo-etching technique. During the processing, by using an anisotropy in the etching direction as well as a fast etching rate in the film thickness direction, the entire film is removed by etching except for the film which remains only on the etched channel sealing portion on the side of the diaphragm.

Subsequently, a polysilicon film 111, which functions as a water-proof layer, is formed by the CVD so that it covers the silicon oxide film on the side of the diaphragm and the polysilicon film on the upper surface of the diaphragm. Because the silicon oxide film formed by the CVD is permeable, covering the surface of the silicon oxide film with an impermeable polysilicon film prevents moisture from penetrating into the cavity, which prevents the occurrence of a change of character.

Finally, as FIG. 14 shows, the etching process progressively removes the polysilicon film 111 and the polysilicon film 109 until it reaches the etching stopper film so that the film thickness at the central portion of the diaphragm becomes sufficient enough to obtain the desired pressure sensitivity. During this process, the etching stopper film prevents the polysilicon film 107, which functions as a diaphragm, from being etched. The above-mentioned processes will complete the gauge structure.

As stated above, by temporarily increasing rigidity of the diaphragm using the reinforcing layer 109 during the sacrificial-layer etching process and removing the reinforcing layer after the sacrificial layer has been etched, it is possible to solve the sticking problem of the diaphragm 7 without sacrificing pressure sensitivity, thereby providing high yield pressure gauges.

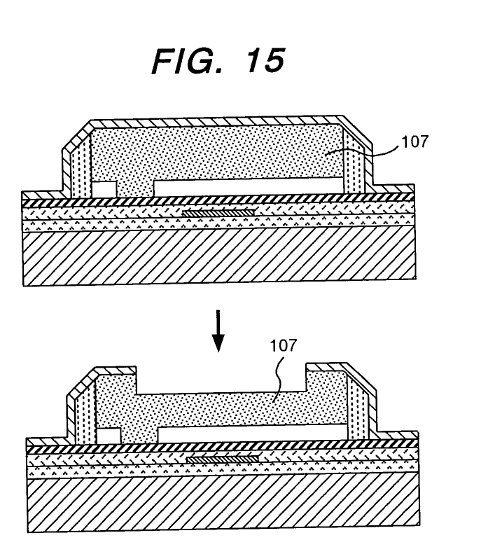

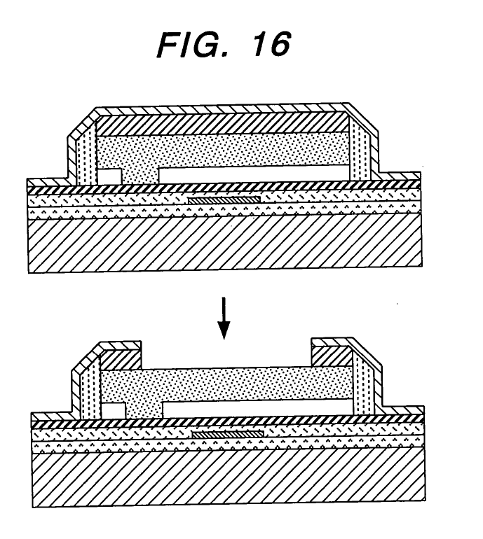

Another method for reinforcing the diaphragm is, as shown in FIG. 15, to accumulate the polysilicon film 107 until the desired thickness is obtained. In this case, in order to obtain desired film rigidity after the sacrificial-layer etching process has been completed, the central portion is etched according to a predetermined etching time, taking into consideration the polysilicon etching rate, so that the amount of film etched is satisfactory. Furthermore, as FIG. 16 shows, there is another method that uses a material different from the diaphragm layer to make a reinforcing layer and does not use an etching stopper layer.

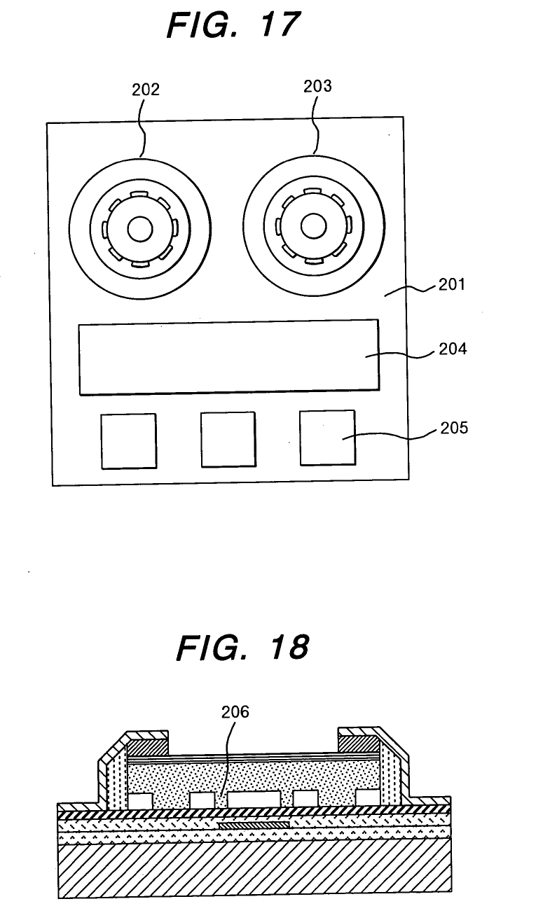

Next, FIG. 17 shows a configuration example of the pressure sensor 201 which integrates a pressure gauge according to the present invention and a capacitance detecting circuit. This sensor consists of a pressure gauge 202, a reference capacitance element 203, a capacitance detecting circuit 204, and an electrode pad 205. Although the reference capacitance element 203 is almost the same shape as the pressure gauge as shown in FIG. 18, it has a supporting post 206 at the central portion of the diaphragm to prevent the capacitance value from changing according to pressure. Herein, when pressure is applied to the pressure sensor, capacitance does not change in the reference capacitance element 203, while capacitance change AC occurs in the pressure gauge 202. This difference is converted to a voltage value by means of a capacitance detecting circuit 204 and the result is then outputted to the electrode pad 205.

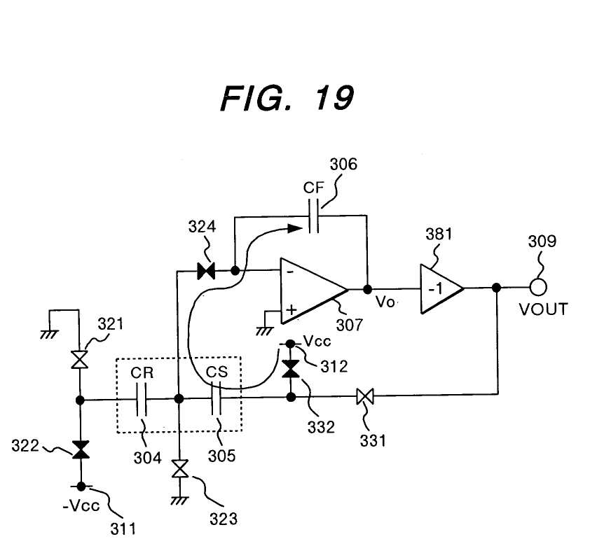

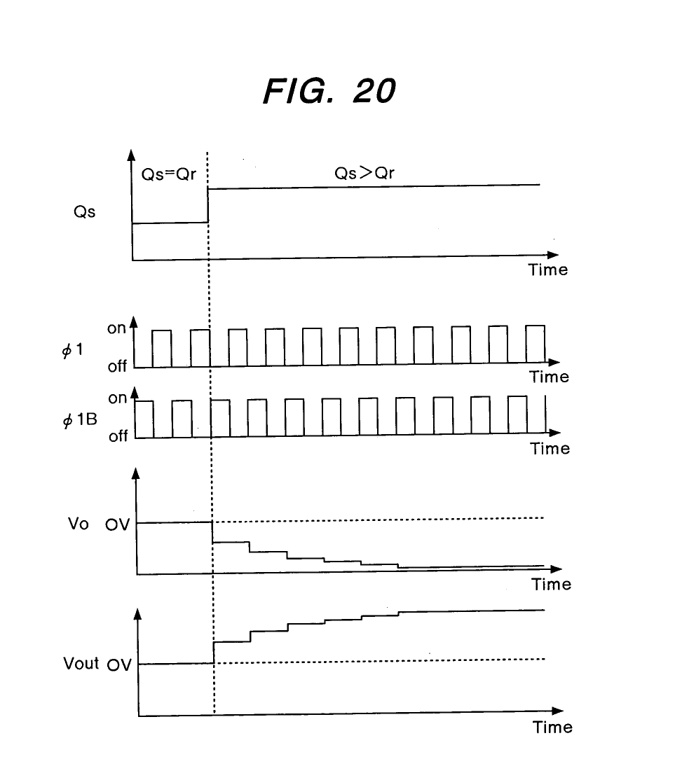

FIG. 19 shows the circuit configuration of the capacitance detecting circuit, and FIG. 20 shows the operational waveform to explain the operations. This embodiment consists of a pressure gauge capacitance (Cs) 305, a reference capacitance element capacitance (Cr) 304, constant voltage sources 311 and 312, switches 321, 322, 323, 324, 331 and 332, a capacitor (Cf) 306, an operational amplifier 307, an inverter 381, and an output terminal 309.

Switches 321, 323 and 331 are driven by drive signal φ1 and switches 322, 324 and 332 are driven in the opposite phase (φ1B).

Furthermore, an inverter 381 multiplies an input signal by −1 and outputs the result, which is easily applied in a simple inverting amplifier that uses an operational amplifier or in a switched capacitor circuit.

Assuming that an initial value is Vout=0V, while switches 321, 323 and 331 are ON, neither Cs nor Cr has been recharged. However, at the moment switches 322, 324 and 332 are turned ON, electric charges Qs and Qr recharge the Cs and Cr respectively. If Qs is equal to Qr, electric current does not flow into integral capacitor CF; consequently, outputs Vo and Vout remain 0V. Herein, if Cs increases due to the application of a force, such as pressure, Qs becomes larger than Qr. As a result, the difference between electric charge Qs that recharges Cs and electric charge Qr that recharges Cr is integrated by capacitor Cf. At this point, voltage Vo is in accordance with Equation 7.

$${V}_{0} = \frac{Cr - Cs}{Cf} Vcc \qquad ( 7 )$$

Because output voltage Vout is −1 times as much as Vo, sensor output Vout is in accordance with Equation 8.

$$Vout = \frac{Cs - Cr}{Cf} Vcc \qquad ( 8 )$$

Therefore, at the next switch operation step, voltage which is equivalent to Vcc−Vout is applied to Cs. Finally, output voltage Vout fluctuates until an electric charge that recharges Cs and an electric charge that recharges Cr become equal, and then Vout becomes stable. The final output voltage is as follows:

$$Vout = ( 1 - \frac{Cr}{Cs} ) Vcc \qquad ( 9 )$$

Creating such a circuit configuration will obtain linear output voltage according to pressure P.

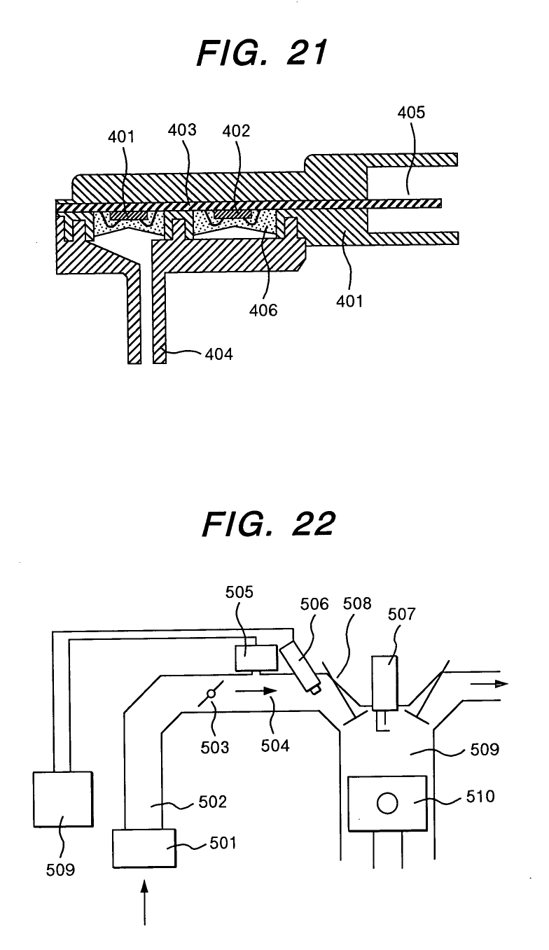

Next, FIG. 21 shows an embodiment which mounts a pressure gauge according to the present invention as a manifold pressure sensor for controlling an automobile engine. The pressure sensor consists of a pressure gauge chip 401, an amplifier circuit chip 402, a lead frame 403 that adheres those chips, a cover with a pressure introducing port 404 and a connector portion 405. After the pressure gauge chip 401 and the amplifier circuit chip 402 have been adhered to the lead frame 403, wire bonding is performed between the chips' terminals and the frame. Subsequently, the upper surface is covered with gel 406, and then the cover with a pressure introducing port 404 is adhered and assembly is completed.

FIG. 22 shows an embodiment that incorporates a pressure sensor manufactured according to the present invention into a manifold pressure sensor of an automobile engine control system. Outside air is directed into an intake tube 502 after it has passed through the air cleaner 501; the flow rate is adjusted by a throttle valve 503; and then the air is directed into an intake manifold 504. A pressure sensor 505 according to the present invention is installed in the intake manifold 504 so as to detect pressure of the intake manifold 504. The engine control unit 509 calculates the amount of intake based on a signal from the pressure sensor 505 and a signal indicating engine revolutions. It then calculates the amount of fuel injection most suitable for the amount of intake and sends an injection signal to an injector 506. Gasoline injected from the injector 506 is mixed with the intake air to become a fuel-air mixture which flows into a combustion chamber 509 when the intake valve 508 opens. It is then compressed by a piston 510, ignited by an ignition plug 507, and explosive combustion occurs.

High reliability and low cost performance are required for a manifold pressure sensor for an automobile engine control system as shown in this embodiment. To reduce pressure sensor cost, it is important to have a high yield manufacturing process. Therefore, applying the above-mentioned concept will prevent diaphragms from being damaged during the manufacturing process thereby increasing yield, which reduces pressure sensor cost.

Moreover, the present invention can be applied to the manufacturing of a diaphragm for a pressure sensor as well as other semiconductor devices that have a movable portion and a minute gap space which can be manufactured using a sacrificial-layer etching method.

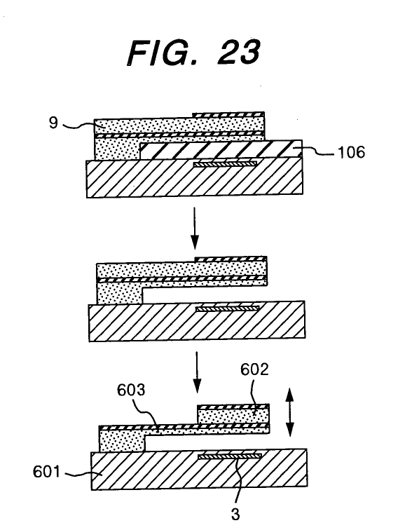

Hereafter, embodiments of those semiconductor devices will be described. With reference to FIG. 23, an embodiment that applies the present invention to a capacitive type acceleration sensor will be explained. The capacitive type acceleration sensor 601 consists of a mass block which also functions as a movable electrode 602, a cantilever beam 603 which supports the mass block, and a fixed electrode 3 which oppositely faces the mass block. The mass block which also functions as a movable electrode 602 fluctuates according to acceleration, causing a gap between the movable electrode and the fixed electrode to change, thereby changing the capacitance. The acceleration sensor utilizes this characteristic, and it is possible to adjust sensitivity to acceleration by adjusting the thickness of the beam film. To increase sensitivity, simply make the film of the beam thin although the sticking problem tends to occur during the sacrificial-layer etching process. Therefore, by using a manufacturing method according to the present invention., it is possible to make the beam film thick during the sacrificial-layer etching process and make the beam film optimally thin after the sacrificial-layer etching process has been completed, thereby increasing yield during the manufacturing process without sacrificing the sensitivity.

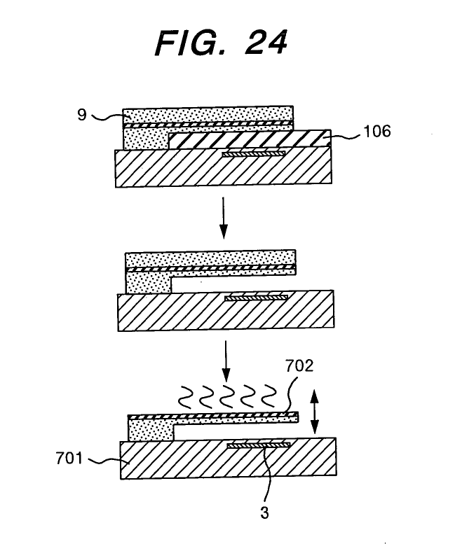

Next, an embodiment that applies the present invention to a capacitive type infrared sensor will be described referring to FIG. 24. The configuration of the capacitive type infrared sensor 701 is similar to that of the above-mentioned capacitive type acceleration sensor; however, it has a movable electrode which has a bimetal structure. The bimetal-structure movable electrode 702 deforms due to heat that is generated when infrared light is absorbed, causing a capacitance change to occur. This characteristic is applied to the infrared sensor. Similar to the manufacturing of the acceleration sensor, by applying the present invention to this infrared sensor, it is possible to prevent the occurrence of the sticking problem during the sacrificial-layer etching process without unnecessarily increasing rigidity of the movable portion.

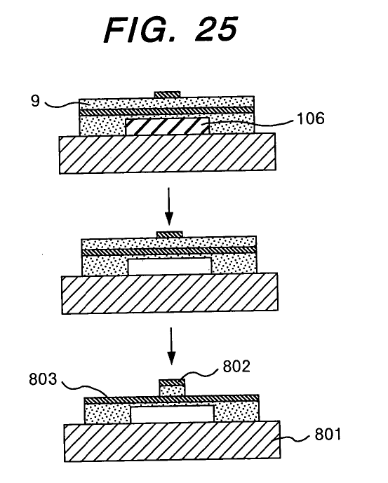

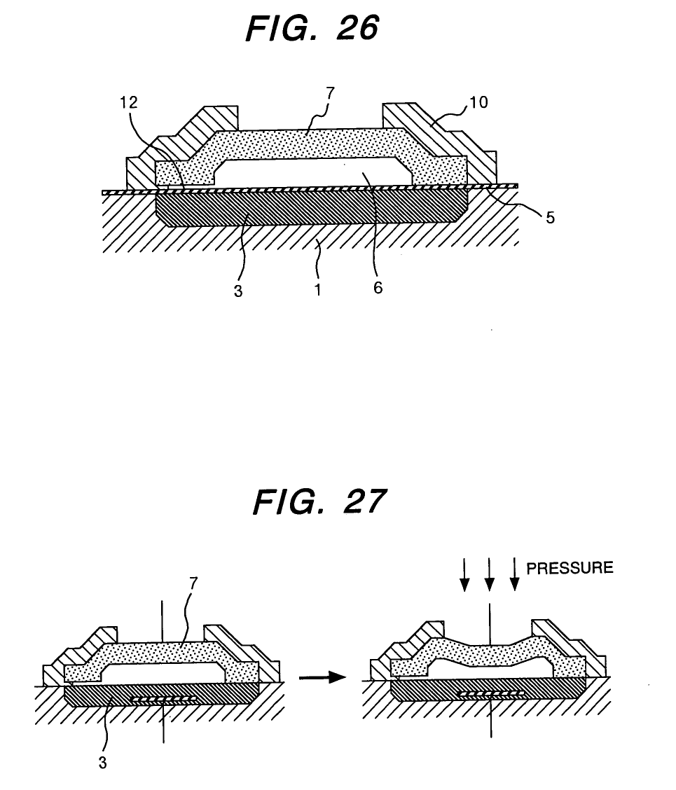

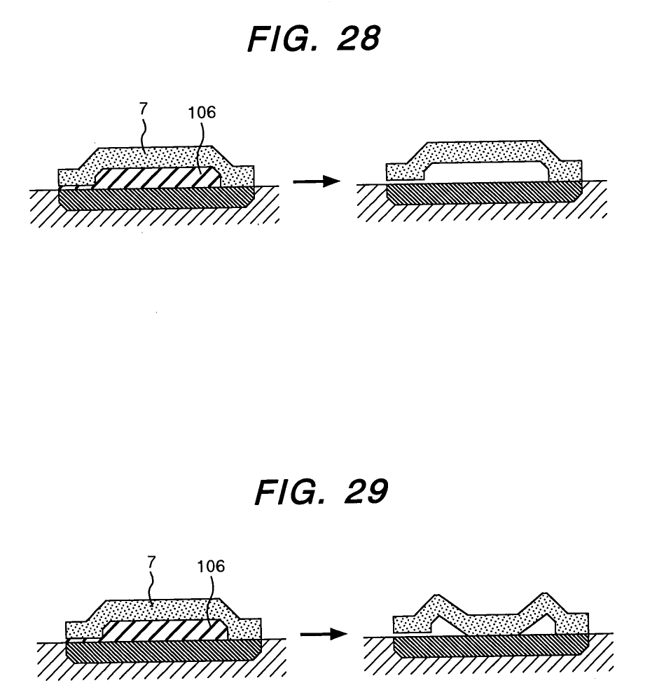

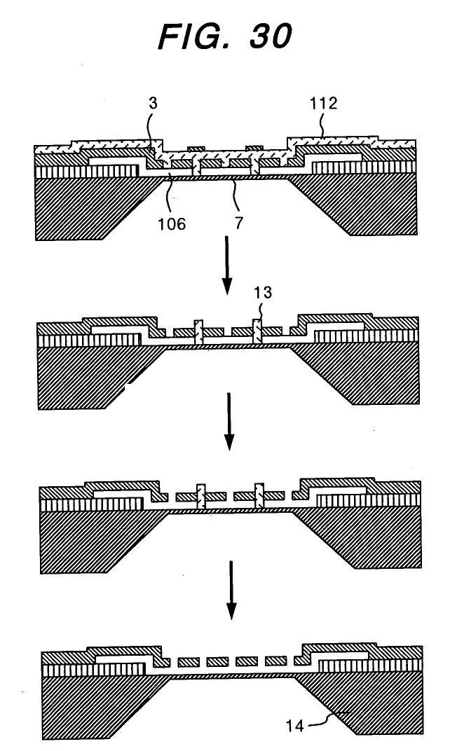

Finally, an embodiment that applies the present invention to an air-flow sensor will be explained referring to FIG. 25. The air-flow sensor 801 has a heater 802 in which an electrical resistance value is extremely temperature dependant. When the heater 802 is exposed to air in an air-flow passage while electricity is turned on, heat dissipates according to the ambient air flow rate, causing the electrical resistance value of the heater 802 to change. This characteristic is used as the air-quantity detection principle. In this sensor, the heater 802 is formed on the diaphragm 803 to reduce heat capacitance and increase response. Although heat capacitance decreases as the diaphragm 803 becomes thinner, the sticking problem during the manufacturing process tends to occur. Therefore, according to the present invention, it is possible to make the diaphragm thick to increase its rigidity during the sacrificial-layer etching process so as to prevent the sticking problem and then make the diaphragm thin after the sacrificial-layer etching process has been completed. As a result, it is possible to increase yield during the manufacturing process and also achieve an air-flow sensor with low heat capacitance.

The present invention solves the sticking problem of the movable portion without unnecessarily increasing rigidity of the movable portion and provides high yield semiconductor devices.

What is claimed is:

1. A method of manufacturing a semiconductor device which is formed by using a sacrificial-layer etching method and has a movable structural body that is located on top of a semiconductor substrate, oppositely facing said semiconductor substrate with a space interposed, wherein
said movable structural body consists of a main configuration member and a reinforcing member during the sacrificial-layer etching process, and a part of or the entire reinforcing member is removed after the sacrificial-layer etching process has been completed.

2. A method of manufacturing a semiconductor device according to claim 1 and 2, wherein said main configuration member and said reinforcing member are made of the same material, and an etching stopper layer which is made of a different material is provided between said members.

3. A method of manufacturing a semiconductor device according to claim 1 and 2, wherein said main configuration member and said reinforcing member are made of different material.

4. A semiconductor device comprising
a semiconductor substrate,
a movable structural body having a periphery portion which comes in contact with said semiconductor substrate and a central portion of said movable structural body oppositely facing said semiconductor substrate with a predetermined gap interposed thereby creating a space, and
a reinforcing member which is disposed in the periphery portion of said movable structural body, wherein
the central portion of said reinforcing member adheres to the central portion of said movable structural body during the sacrificial-layer etching process and is removed after the sacrificial-layer etching process has been completed.

5. A semiconductor device comprising
a semiconductor substrate,
a movable structural body having a periphery portion which comes in contact with said semiconductor substrate and a central portion of said movable structural body oppositely facing said semiconductor substrate with a predetermined gap interposed thereby creating a space,
a reinforcing member which is disposed in the periphery portion of said movable structural body and made of the same material as said movable structural body, and
an etching stopper layer which is inserted between said movable structural body and said reinforcing member and is made of different material, wherein
the central portion of said reinforcing member adheres to the central portion of said movable structural body during the sacrificial-layer etching process and is removed after the sacrificial-layer etching process has been completed.

6. A semiconductor device according to claim 5, wherein said movable structural body and said reinforcing member are made of different material.
